(19) United States
(12) Patent Application Publication
(10) Pub. No.: US 2025/0030222 A1
(43) Pub. Date: Jan. 23, 2025

(54) NITRIDE SEMICONDUCTOR LASER ELEMENT

(71) Applicants: Ushio Denki Kabushiki Kaisha, Tokyo (JP); OSAKA UNIVERSITY, Osaka (JP)

(72) Inventors: Toshihiko FUKAMACHI, Tokyo (JP); Masahiro UEMUKAI, Suita-shi (JP); Ryuji KATAYAMA, Suita-shi (JP); Tomoyuki TANIKAWA, Suita-shi (JP)

(73) Assignees: Ushio Denki Kabushiki Kaisha, Tokyo (JP); OSAKA UNIVERSITY, Osaka (JP)

(21) Appl. No.: 18/778,552

(22) Filed: Jul. 19, 2024

(30) Foreign Application Priority Data
Jul. 21, 2023 (JP) 2023-119337

(51) Int. Cl. H01S 5/12; H01S 5/22

(52) U.S. Cl. CPC H01S 5/1225; H01S 5/124; H01S 5/2216

(57) ABSTRACT

In a distributed feedback semiconductor laser element, a multi-layered structure includes a GaN substrate, an n-type semiconductor layer, an active layer, and a p-type semiconductor layer, and a ridge waveguide is formed. A first diffraction grating is formed adjacent to and on both sides of the ridge waveguide. A depth d of a groove of the first diffraction grating is included in the range of 50 nm d≤200 nm, and a duty ratio duty is included in the range of an inequality (1) using constants a, b, c, and n defined for the order of the diffracted light.

$$- \sqrt[n]{\frac{d - c}{a}} + b ≦ duty ≦ \sqrt[n]{\frac{d - c}{a}} + b \qquad ( 1 )$$

### BACKGROUND

### 1. Technical Field

The present disclosure relates to a nitride semiconductor laser element.

### 2. Description of the Related Art

Hitherto, 254 nm ultraviolet ray sterilization lamps and the like have been widely used for sterilization applications. However, there has been a risk of developing skin cancer or keratitis when irradiation is performed on a person. On the other hand, in recent years, it has been reported from many medical institutions, universities, and the like in Japan and abroad that ultraviolet rays at 222 nm using a KrCl excimer lamp is much safer. In addition, the effect of a KrCl excimer lamp on the coronavirus is being verified. A virus inactivation system to which this KrCl excimer lamp is applied attracts attention as being capable of inactivating viruses without restricting human activities in medical institutions, schools, public and commercial facilities, eating and drinking facilities, and the like, and contributing to both pandemic control and social activities.

For more quietness and downsizing of the virus inactivation system, a method of replacing the KrCl excimer lamp with a semiconductor light emitting device on which a semiconductor light emitting element is mounted is considered. However, there is still no semiconductor light emitting element that emits light around 222 nm. Therefore, a method of converting 444 nm light into 222 nm second harmonic (SHG: second harmonic generation wave) using harmonic generation by a wavelength conversion element is considered.

In order to increase the conversion efficiency of SHG waves, a longitudinal single-mode and high-output semiconductor laser is required as a light source at 444 nm. Generally, as a longitudinal single-mode laser, a distributed feedback laser diode (DFB-LD) is used.

GaN-based materials are widely used as semiconductor light emitting elements that emit light in a wavelength band of ultraviolet light or visible light. However, in a GaN-based material, it is difficult to obtain a sufficient refractive index difference, and it is difficult to increase an optical coupling coefficient κ of the diffraction grating.

### SUMMARY

The present disclosure has been made in such a situation, and an exemplary object of one aspect thereof is to provide a semiconductor laser element capable of obtaining high output in a longitudinal single mode.

One aspect of the present disclosure relates to a distributed feedback semiconductor laser element. The semiconductor laser element includes: a multi-layered structure including a GaN substrate, a first conductivity-type semiconductor layer, a light emitting layer, and a second conductivity-type semiconductor layer, in which a ridge waveguide is formed; and a first diffraction grating formed adjacent to and on both sides of the ridge waveguide. A depth d of a groove of the first diffraction grating is included in the range of 50 nm≤d≤200 nm, and a duty ratio duty is included in the range of an inequality (1) using constants a, b, c, and n defined for the order of the diffracted light.

$$- \sqrt[n]{\frac{d - c}{a}} + b ≦ duty ≦ \sqrt[n]{\frac{d - c}{a}} + b \qquad ( 1 )$$

Another aspect of the present disclosure relates to a method of manufacturing a distributed feedback semiconductor laser element. This manufacturing method includes the steps of: forming a multi-layered structure including a GaN substrate, a first conductivity-type semiconductor layer, a light emitting layer, and a second conductivity-type semiconductor layer; forming a ridge stripe structure in the multi-layered structure; forming a first diffraction grating adjacent to the ridge stripe structure; and forming an insulating film inside a groove of the first diffraction grating. A depth d of the groove of the first diffraction grating is included in the range of 54.9 nm≤d≤200 nm, and a duty ratio duty is included in the range of an inequality (1) using constants a, b, c, and n defined for the order of the diffracted light.

It is to be noted that any arbitrary combination or rearrangement of the above-described structural components and so forth is effective as and encompassed by the present embodiments. Moreover, all of the features described in this summary are not necessarily required by embodiments so that the embodiment may also be a sub-combination of these described features. In addition, embodiments may have other features not described above.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a perspective view of a distributed feedback semiconductor laser element according to First Embodiment;

FIG. 2 is a diagram illustrating interaction between light and a diffraction grating;

FIG. 3 is a diagram illustrating a relationship between a duty ratio of a diffraction grating and an optical coupling coefficient κ;

FIG. 4 is a diagram illustrating a relationship between a groove depth d and a duty ratio duty when the optical coupling coefficient κ is 10 cm⁻¹;

FIG. 5 is a perspective view of a semiconductor laser element according to Second Embodiment;

FIG. 6 is a diagram illustrating interaction between light and a first diffraction grating and a second diffraction grating;

FIG. 7 is a diagram illustrating an optical coupling coefficient κ of First Embodiment and Second Embodiment;

FIG. 8 is a diagram for explaining a method of manufacturing the semiconductor laser element;

FIG. 9 is a perspective view of a semiconductor laser element according to Third Embodiment;

FIG. 10 is a cross-sectional view illustrating a diffraction grating having a phase shift region; and

FIG. 11 is a diagram illustrating a light emitting device according to an embodiment.

### DETAILED DESCRIPTION

### Outline of Embodiment

An outline of several example embodiments of the disclosure follows. This outline is provided for the convenience of the reader to provide a basic understanding of such embodiments and does not wholly define the breadth of the disclosure. This outline is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “one embodiment” may be used herein to refer to a single embodiment or multiple embodiments of the disclosure.

A distributed feedback semiconductor laser element according to one embodiment includes: a multi-layered structure including a GaN substrate, a first conductivity-type semiconductor layer, a light emitting layer, and a second conductivity-type semiconductor layer, in which a ridge waveguide is formed; and a first diffraction grating formed adjacent to and on both sides of the ridge waveguide. A depth d of a groove of the first diffraction grating is included in the range of 50 nm≤d≤200 nm, and a duty ratio duty is included in the range of an inequality (1) using constants a, b, c, and n defined for the order of the diffracted light.

$$- \sqrt[n]{\frac{d - c}{a}} + b ≦ duty ≦ \sqrt[n]{\frac{d - c}{a}} + b \qquad ( 1 )$$

By setting the duty ratio within the range defined by the inequality (1) with the depth of the groove of the diffraction grating as a parameter, a large optical coupling coefficient κ can be obtained, and the output of the semiconductor laser element can be increased.

In one embodiment, the order is 3, a=1000000, b=0.889, c=75.3, n=4, and 75.3 nm≤d≤200 nm may be satisfied.

In one embodiment, the order is 1, a=7500000, b=0.738, c=54.9, n=8, and 54.9 nm≤d≤200 nm may be satisfied.

In one embodiment, the order is 5, a=7500000, b=0.929, c=88.9, n=4, and 88.9 nm≤d≤200 nm may be satisfied.

In one embodiment, the order is 7, a=23000000, b=0.947, c=100.6, n=4, and 100.6 nm≤d≤200 nm may be satisfied.

In one embodiment, the semiconductor laser element may further include a second diffraction grating formed on the upper surface of the ridge waveguide. The first diffraction grating and the second diffraction grating have the same periodic structure and are continuous in plan view. By providing the second diffraction grating, the optical coupling coefficient can be further increased. Furthermore, since the first diffraction grating and the second diffraction grating have the same periodic structure, the first diffraction grating and the second diffraction grating can be simultaneously formed using the same manufacturing process. This facilitates manufacturing.

In an embodiment, the bottom surface of the groove of the second diffraction grating may be higher than the bottom surface of the groove of the first diffraction grating.

In an embodiment, the first diffraction grating may have a phase shift region. In an embodiment, when the oscillation wavelength is λ, m is 0 or any positive integer, and n₀_{ᵣ} is an average refractive index felt by light, the length of the phase shift region may be λ/4n₀_{ᵣ}×(2m+1).

In one embodiment, the phase shift region may be provided at a position that divides an area between the low reflection end surface and the high reflection end surface of the semiconductor laser element in the range of 6:4 to 8:2.

In one embodiment, at least a portion of the first diffraction grating from which light leaks may be covered with an insulating film, and the insulating film may contain at least one or more elements of Si, Zr, Al, Ta, Nb, Ti, In, O, and N.

A light emitting device according to one embodiment may include the distributed feedback semiconductor laser element according to any one of the above embodiments, a nonlinear optical element structured to generate a second harmonic of emission light of the distributed feedback semiconductor laser element, and a filter structured to transmit the second harmonic. According to this configuration, highly safe ultraviolet rays can be generated with high efficiency.

A method of manufacturing a distributed feedback semiconductor laser element according to one embodiment includes the steps of: forming a multi-layered structure including a GaN substrate, a first conductivity-type semiconductor layer, a light emitting layer, and a second conductivity-type semiconductor layer; forming a ridge stripe structure in the multi-layered structure; forming a first diffraction grating adjacent to the ridge stripe structure; and forming an insulating film inside a groove of the first diffraction grating. A depth d of the groove of the first diffraction grating is included in the range of 54.9 nm≤d≤200 nm, and a duty ratio duty is included in the range of an inequality (1) using constants a, b, c, and n defined for the order of the diffracted light.

The manufacturing method according to one embodiment may further include a step of forming a second diffraction grating in a region adjacent to the ridge stripe structure simultaneously with formation of the first diffraction grating.

In one embodiment, the insulating film may be formed by an atomic layer deposition (ALD) method.

### EMBODIMENT

Hereinafter, a preferred embodiment will be described with reference to the drawings. The same or equivalent components, members, and processing illustrated in the drawings are denoted by the same reference numerals, and redundant description will be omitted as appropriate. In addition, the embodiments are not intended to limit the disclosure or the invention, but are merely examples, and all features described in the embodiments and combinations thereof are not necessarily essential to the disclosure or the invention.

In addition, dimensions (thickness, length, width, and the like) of each member described in the drawings may be appropriately enlarged or reduced for easy understanding. Furthermore, the dimensions of the plurality of members do not necessarily indicate the magnitude relationship therebetween, and even if a certain member A is drawn thicker than another member B in the drawing, the member A may be thinner than the member B.

### First Embodiment

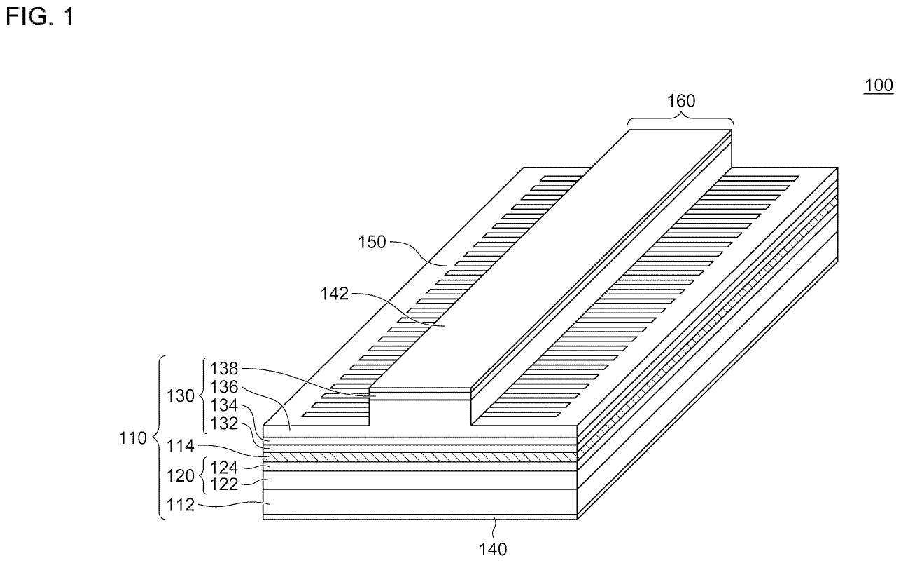

FIG. 1 is a perspective view of a distributed feedback semiconductor laser element 100 according to First Embodiment. The semiconductor laser element 100 includes an n-type GaN substrate 112, an n-type semiconductor layer 120, an active layer 114, a p-type semiconductor layer 130, an n-side electrode 140, a p-side electrode 142, and a diffraction grating 150.

The GaN substrate 112 is a nitride semiconductor and can have a composition of InₓAl_{y}Ga_{1-x-y}N (0≤x≤1, 0≤y≤1, 0≤x+y≤1). In order to generate a 444 nm blue laser beam, the GaN substrate 112 may be made of GaN (x=y=0).

The n-type semiconductor layer 120, the active layer 114, and the p-type semiconductor layer 130 are sequentially formed on the n-type GaN substrate 112 by epitaxial growth to form the multi-layered structure 110.

The n-type semiconductor layer 120 may include an n-type cladding layer 122 and an n-type guide layer 124. For example, the material of the n-type cladding layer 122 is n-Al_{0.05}Ga_{0.95}N, and the material of the n-type guide layer 124 is n-GaN.

The active layer (light emitting layer) 114 having a quantum well structure is formed on the n-type semiconductor layer 120. When the oscillation wavelength is 444 nm, In_{0.01}Ga_{0.99}N can be selected as the barrier layer and In_{0.15}Ga_{0.85}N can be selected as the well layer as the material of the quantum well structure.

In order to curb diffusion of impurities from the n-type semiconductor layer 120 to the active layer 114, an undoped nitride guide layer (not illustrated) In_{0.02}Ga_{0.98}N can be inserted therebetween.

The p-type semiconductor layer 130 may include a carrier block (electron block EB) layer 132, a p-type guide layer 134, a p-type cladding layer 136, and a contact layer 138. For example, the material of the p-type guide layer 134 is p-In_{0.02}Ga_{0.98}N, the material of the p-type cladding layer 136 is p-Al_{0.04}Ga_{0.96}N, and the material of the contact layer 138 is p-GaN.

In order to curb diffusion of impurities from the p-type semiconductor layer 130 to the active layer 114, an undoped nitride guide layer (not illustrated) can be inserted therebetween.

The n-side electrode 140 is formed on the back surface of the GaN substrate 112, and the p-side electrode 142 is formed on the upper surface of the contact layer 138.

A ridge (mesa) is formed in the p-type cladding layer 136, and a ridge stripe structure (ridge structure) 160 is formed. The ridge can be several hundred nanometers in height and several microns in ridge width (mesa width). For example, the height may be 500 nm and the width may be 2 μm.

An optical coupling coefficient κ to be described later also changes depending on the ridge width, and the optical coupling coefficient κ increases as the mesa width is narrowed. Note, however, that when the mesa width becomes less than 1 μm, the lateral confinement becomes weak, and the optical coupling coefficient also starts to decrease. On the other hand, when the mesa width exceeds 3 μm, the transverse single mode is changed to the transverse multi mode. Therefore, in order to obtain a high optical coupling coefficient κ in the transverse single mode, a mesa width Wm is preferably 1 μm Wm 3 μm.

The p-type cladding layer 136 having the ridge stripe structure 160 forms a ridge waveguide together with the active layer 114 and the n-type cladding layer 122.

The diffraction grating 150 is formed in a mesa-side portion of the p-type cladding layer 136 adjacent to the ridge stripe structure 160.

Note that AR (antireflection) coating (reflectance of 2% or less) is applied to an emission side (front) end surface of the semiconductor laser element 100, and HR (high reflection) coating (reflectance of 90% or more) is applied to a reflection side (rear) end surface of the semiconductor laser element 100. Alternatively, both end surfaces may be AR coated.

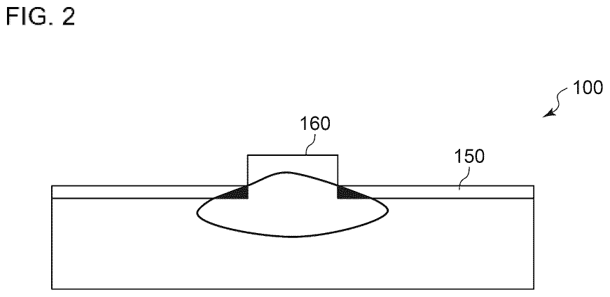

FIG. 2 is a diagram illustrating interaction between light and the diffraction grating 150. FIG. 2 is a simplified cross-sectional view of the semiconductor laser element 100. The laser beam guided in the ridge waveguide seeps in the horizontal transverse direction, and the seeped portion interacts with the diffraction grating 150 beside the ridge stripe structure 160. This allows the laser to operate as a distributed feedback laser and to oscillate in longitudinal single mode.

The shape of the groove of the diffraction grating 150 is generally considered to be a rectangular shape, but is not limited thereto as long as a similar effect can be effectively obtained. For example, the cross-sectional shape of the groove may be a trapezoidal shape, a wedge shape, or other shapes. If the cross-section of the groove is non-rectangular, its width may be defined as the average width.

Next, the diffraction grating 150 for obtaining a high output at 444 nm will be described. In a long-wavelength (red to infrared) semiconductor laser, the optical coupling coefficient κ of the diffraction grating can be easily increased, but in a blue laser, it is difficult to increase the optical coupling coefficient κ, and the structure of the diffraction grating 150 greatly affects the performance of the semiconductor laser element 100.

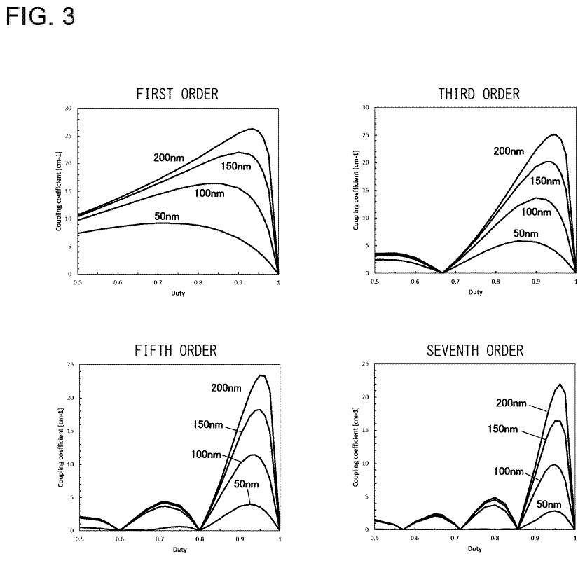

FIG. 3 is a diagram illustrating a relationship between a duty ratio of a diffraction grating and the optical coupling coefficient κ. In FIG. 3, the optical coupling coefficient κ is calculated for the first-order, third-order, fifth-order, and seventh-order diffracted light. The depths of the grooves are 50 nm, 100 nm, 150 nm, and 200 nm, respectively. The duty ratio of the diffraction grating is represented by a ratio of a width and a period of the groove of the diffraction grating. When the width of the groove is denoted by w and the period is denoted by p, duty=1−(w/p), which is defined in a range of 0≤duty≤1, and the duty ratio increases as the width w of the groove is narrower.

One of important parameters for designing the DFB-LD is a normalized coupling coefficient κL. Here, κ is an optical coupling coefficient, and L is a resonator length. This κL may empirically be κL≥0.5, more desirably κL≥1. This is because, in DFB-LD having the small κL, the FP (Fabry-Perot) mode and the DFB mode may be mixed depending on the driving condition, and the longitudinal single-mode oscillation having the high SMSR (side mode suppression ratio) cannot be achieved. In addition, in the transverse single-mode nitride semiconductor laser, since the ridge width is about 2 μm, in order to obtain a light output of several 10 mW or more, it is empirically desirable to set the resonator length to 500 μm or more. This is because heat saturation generally occurs in light output due to heat generated by energization, but when the resonator length is short, heat saturation occurs before sufficient light output is obtained. For these reasons, it is desirable to design the optical coupling coefficient κ of DFB-LD so that κ≥10 cm⁻¹.

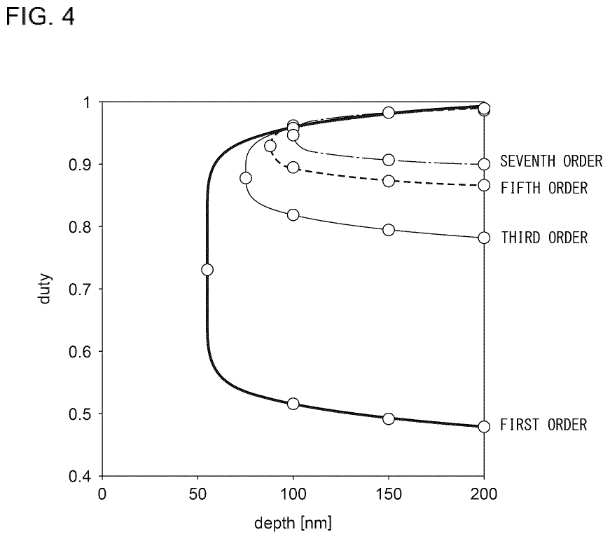

FIG. 4 is a diagram illustrating a range of a groove depth d and a duty ratio duty when the optical coupling coefficient κ obtained from the result of FIG. 3 is 10 cm⁻¹ or more. FIG. 4 can be well expressed by the following expression (2).

$$d = a \times {( duty - b )}^{n} + c \qquad ( 2 )$$

a, b, c, and n are fitting parameters. For a certain depth d, the optical coupling coefficient κ can be made larger than 10 cm⁻¹ by determining the duty ratio duty within a range surrounded by expression (2). That is, the duty ratio duty may be determined so as to satisfy the following relational expression (1).

$$- \sqrt[n]{\frac{d - c}{a}} + b ≦ duty ≦ \sqrt[n]{\frac{d - c}{a}} + b \qquad ( 1 )$$

Here, the optical coupling coefficient κ depends on the depth d of the groove, and the optical coupling coefficient tends to monotonically increase as the groove is dug deeper. However, the groove cannot be deepened unlimitedly due to restrictions of an etching technique or the like, and the optical coupling coefficient κ is about 200 nm at most. In addition, when the depth of the diffraction grating d is to be made deeper than 200 nm, it is necessary to increase the height (mesa height) of the ridge stripe structure 160 in order to ensure sufficient light confinement in the lateral direction, but this causes an increase in the driving voltage. In consideration of such a constraint condition, the groove depth d is preferably in the range of 50 to 200 nm.

In one example, the diffraction order can be 3. In this case, a=1000000, b=0.889, c=75.3, n=4, and the possible groove depth d is 75.3 nm≤d≤200 nm.

In one example, the diffraction order can be 1. In this case, a=7500000, b=0.738, c=54.9, n=8, and the possible groove depth d is 54.9 nm≤d≤200 nm.

In one example, the diffraction order can be 5. In this case, a=7500000, b=0.929, c=88.9, n=4, and the possible groove depth d is 88.9 nm≤d≤200 nm.

In one embodiment, the diffraction order can be 7. In this case, a=23000000, b=0.947, c=100.6, n=4, and the possible groove depth d is 100.6 nm≤d≤200 nm.

### Second Embodiment

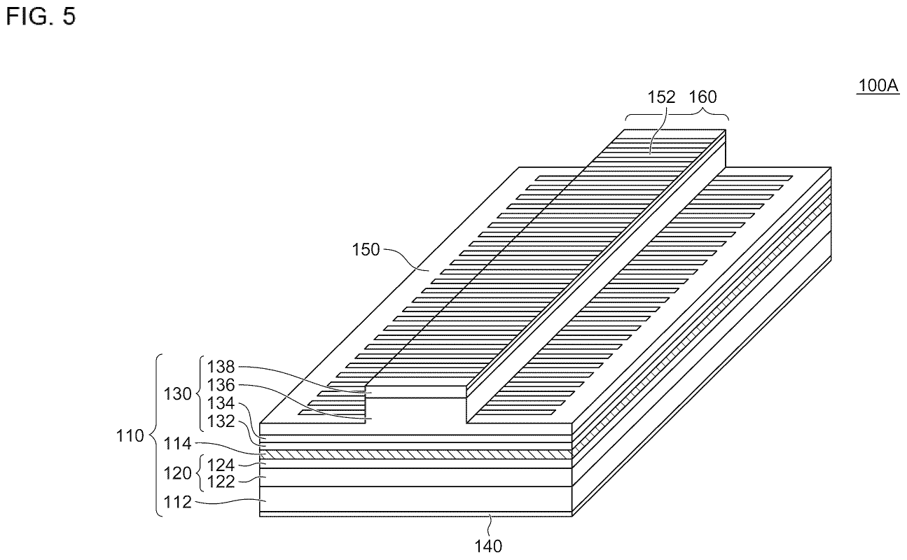

FIG. 5 is a perspective view of a semiconductor laser element 100A according to Second Embodiment. The semiconductor laser element 100A further includes a second diffraction grating 152 in addition to the semiconductor laser element 100 of FIG. 1. In Second Embodiment, the diffraction grating 150 adjacent to a ridge stripe structure 160 is referred to as a first diffraction grating 150.

The second diffraction grating 152 has the same periodic structure as the first diffraction grating 150, and when the semiconductor laser element 100A is viewed in plan view, the positions of the corresponding grooves of the first diffraction grating 150 and the second diffraction grating 152 are aligned and continuous.

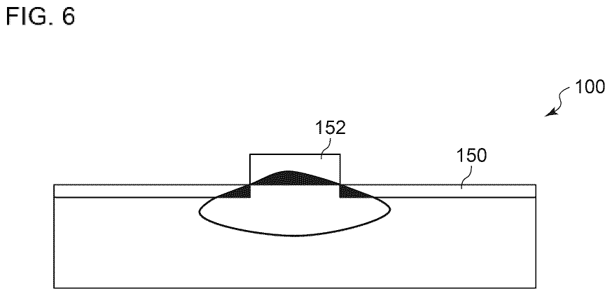

FIG. 6 is a diagram illustrating interaction between light and the first diffraction grating 150 and the second diffraction grating 152. FIG. 6 is a simplified cross-sectional view of the semiconductor laser element 100A. The laser beam guided in the ridge waveguide seeps in the horizontal transverse direction, and the seeped portion interacts with the first diffraction grating 150 beside the ridge stripe structure 160. In addition, the laser beam also seeps vertically upward, and the seepage acts on the second diffraction grating 152 on the ridge stripe structure 160. As a result, the optical coupling coefficient κ can be further increased as compared with First Embodiment.

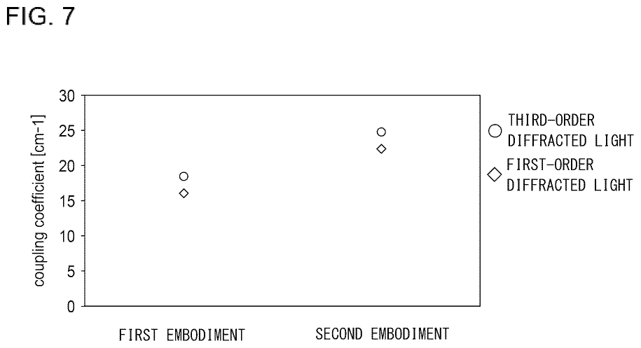

FIG. 7 is a diagram illustrating an optical coupling coefficient κ of First Embodiment and Second Embodiment. The calculation was performed on the third-order diffracted light and the first-order diffracted light. In the third-order diffracted light, the groove depth d is 150 nm and the duty ratio is 90%, and in the first-order diffracted light, the groove depth d is 100 nm and the duty ratio is 85%. In Second Embodiment, the optical coupling coefficient κ can be increased for both the first-order diffracted light and the third-order diffracted light.

Furthermore, since the first diffraction grating and the second diffraction grating have the same periodic structure, the semiconductor laser element 100A according to Second Embodiment can be simultaneously formed using the same manufacturing process. In this case, the depths of the grooves of the diffraction gratings 150 and 152 are substantially the same. In other words, the bottom of the groove of the diffraction grating 150 is positioned higher than the bottom of the groove of the diffraction grating 152.

When the depth of the diffraction grating d is to be made deeper than 200 nm, it is necessary to increase the height (mesa height) of the ridge stripe structure 160 in order to ensure sufficient light confinement in the lateral direction, but this causes an increase in the driving voltage. In addition, the injection current tends to be non-uniform in the resonator direction. On the other hand, by limiting the depth d of the groove of the diffraction grating to the range of 50 to 200 nm, it is not necessary to increase the height of the mesa, so that problems such as voltage rise and non-uniformity of current do not occur.

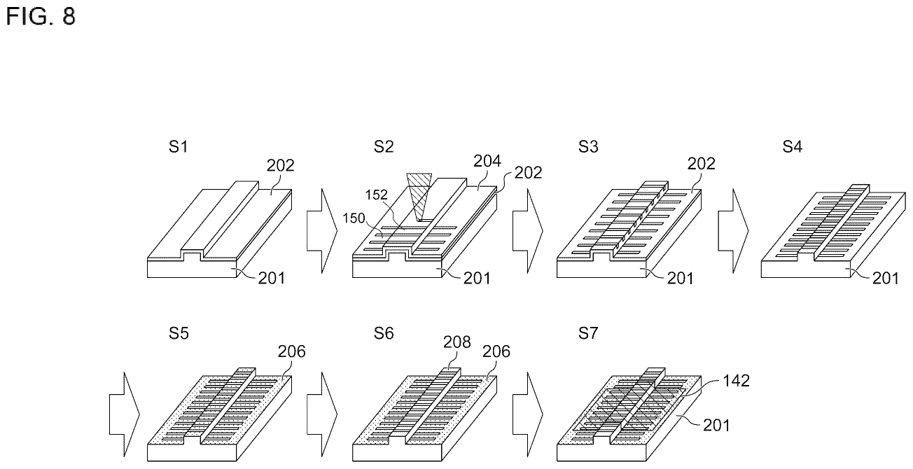

FIG. 8 is a diagram for explaining a method of manufacturing the semiconductor laser element 100A. In step S1, an insulating film 202 is formed on a multi-layered structure 201 in which the mesa is formed. The multi-layered structure 201 is a multi-layered structure including the GaN substrate 112, the n-type semiconductor layer 120, the active layer 114, and the p-type semiconductor layer 130 of FIG. 1. A known technique may be used as a method of manufacturing the multi-layered structure.

In subsequent step S2, after a resist 204 is applied onto the insulating film 202, a pattern of the diffraction gratings 150 and 152 is formed.

In subsequent step S3, the insulating film 202 is etched to remove the resist 204. In subsequent step S4, the insulating film 202 is removed.

An insulating film 206 is desirably formed inside the groove. The insulating film 206 is preferably formed at least at a portion where light seeps out, and may completely fill the groove. In step S5, the insulating film 206 is formed by an atomic layer deposition (ADL) method. By using the ADL method, the insulating film 206 can be successfully formed on the bottom surface of the groove. As a material of the insulating film 206, an oxide containing one or more elements of Si, Zr, Al, Ta, Nb, Ti, In, O, and N, specifically, SiNₓ, SiO₂, ZrO₂, Al₂O₃, Ta₂O₅, Nb₂O₅, TiO₂, AlN, AlON, AlInN, or the like can be used.

In subsequent step S6, a part 208 of the upper surface of the mesa in the insulating film 206 is removed. Then, in step S7, the p-side electrode 142 is formed.

The above is the method of manufacturing the semiconductor laser element 100A. According to the semiconductor laser element 100A, the first diffraction grating 150 and the second diffraction grating 152 can be simultaneously formed by the same process.

In the semiconductor laser element 100 according to First Embodiment, it is necessary to form the diffraction grating 150 while avoiding the mesa, and thus, the degree of difficulty in manufacturing is high. That is, if the diffraction grating 150 is brought close to the vicinity of the shoulder of the mesa, the possibility that a groove is formed on the side surface of the mesa increases. On the other hand, in order to prevent the groove on the side surface of the mesa, the diffraction grating 150 is separated from the shoulder of the mesa, and the optical coupling coefficient κ decreases. In Second Embodiment, since the first diffraction grating 150 and the second diffraction grating 152 are simultaneously formed by the same process, such a problem does not occur.

### Third Embodiment

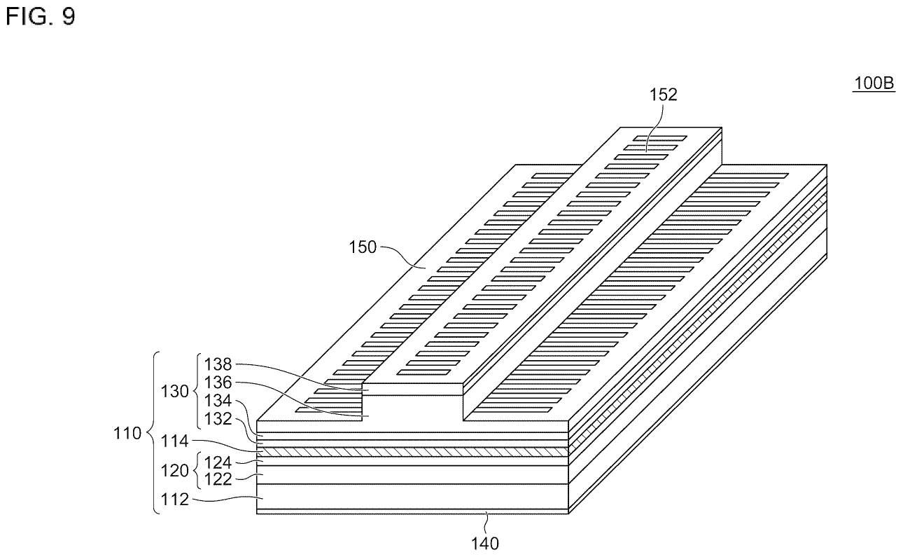

FIG. 9 is a perspective view of a semiconductor laser element 100B according to Third Embodiment. A second diffraction grating 152 is formed on the upper surface of the mesa, but no groove is formed at a certain width from the side surface of the mesa. As a result, non-uniformity of current injection can be further curbed.

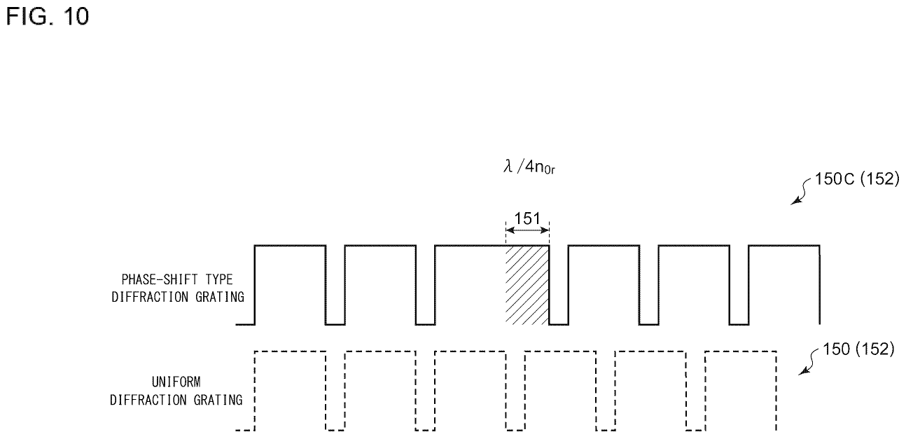

In First to Third Embodiments, phase shift regions may be provided in the diffraction gratings 150 and 152. FIG. 10 is a cross-sectional view illustrating a diffraction grating 150C having a phase shift region 151. The lower part of FIG. 10 illustrates the diffraction grating 150 not including the phase shift region 151 for comparison. The phase shift region 151 is provided at a peak portion of the diffraction grating 150C. The length of the phase shift region 151 can be

λ/4n₀_{ᵣ}×(2m+1) λ is an oscillation wavelength, m is 0 or any positive integer, and n₀_{ᵣ} is an average refractive index felt by light. n₀_{ᵣ} is a value depending on the structure or material of the semiconductor laser element, and can take a value in a range of 1<n₀_{ᵣ}<3. By providing the phase shift region 151, the longitudinal single-mode side mode suppression ratio (SMSR) can be improved.

The phase shift region 151 is preferably formed closer to the high reflection end surface than the center of the resonator. For example, the phase shift region 151 may be provided at a position that divides the area between the low reflection end surface (emission end surface) and the high reflection end surface of the semiconductor laser element in the range of 6:4 to 8:2.

Next, applications of the semiconductor laser element 100 will be described.

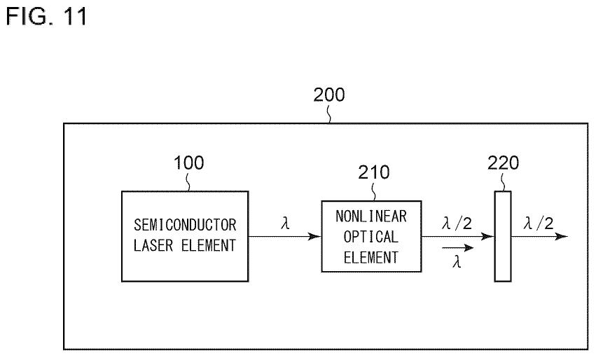

FIG. 11 is a diagram illustrating a light emitting device 200 according to an embodiment. The light emitting device 200 includes the above-described semiconductor laser element 100 (100A, 100B), a nonlinear optical element 210, and a filter 220.

The semiconductor laser element 100 oscillates in a longitudinal single mode at λ=444 nm. The nonlinear optical element 210 is a wavelength conversion element, and generates the second harmonic λ/2 (wavelength of 222 nm) of light emitted from the semiconductor laser element 100. As the nonlinear optical element 210, for example, β-BaB₂O₄ (BBO), CsLiB₆O₁₀ (CLBO), or the like is used. By injecting the fundamental wave (444 nm) into this wavelength conversion element from the appropriate direction, the second harmonic wave (222 nm) can be generated. The filter 220 is a short-pass filter, removes the fundamental wave λ, and emits the second harmonic λ/2.

While the preferred embodiments of the present disclosure have been described using specific terms, such description is for illustrative purposes only, and it is to be understood that changes and variations may be made without departing from the spirit or scope of the appended claims.

What is claimed is:

1. A distributed feedback semiconductor laser element, the semiconductor laser element comprising:
a multi-layered structure including a GaN substrate, a first conductivity-type semiconductor layer, a light emitting layer, and a second conductivity-type semiconductor layer, in which a ridge waveguide is formed; and
a first diffraction grating formed adjacent to and on both sides of the ridge waveguide, wherein
a groove depth d of the first diffraction grating is included in a range of 50 nm≤d≤200 nm, and a duty ratio duty is included in a range of an inequality (1):
$$- \sqrt[n]{\frac{d - c}{a}} + b ≦ duty ≦ \sqrt[n]{\frac{d - c}{a}} + b \qquad ( 1 )$$
using constants a, b, c, and n defined for an order of diffracted light.

2. The semiconductor laser element according to claim 1, wherein the order is 3, a=1000000, b=0.889, c=75.3, n=4, and 75.3 nm≤d≤200 nm.

3. The semiconductor laser element according to claim 1, wherein the order is 1, a=7500000, b=0.738, c=54.9, n=8, and 54.9 nm≤d≤200 nm.

4. The semiconductor laser element according to claim 1, wherein the order is 5, a=7500000, b=0.929, c=88.9, n=4, and 88.9 nm≤d≤200 nm.

5. The semiconductor laser element according to claim 1, wherein the order is 7, a=23000000, b=0.947, c=100.6, n=4, and 100.6 nm≤d≤200 nm.

6. The semiconductor laser element according to claim 1, further comprising a second diffraction grating formed on an upper surface of the ridge waveguide.

7. The semiconductor laser element according to claim 6, wherein a bottom surface of a groove of the second diffraction grating is higher than a bottom surface of a groove of the first diffraction grating.

8. The semiconductor laser element according to claim 1, wherein the first diffraction grating has a phase shift region.

9. The semiconductor laser element according to claim 8, wherein the phase shift region is provided at a position that divides an area between a low reflection end surface and a high reflection end surface of the semiconductor laser element in a range of 6:4 to 8:2.

10. The semiconductor laser element according to claim 1, wherein in at least a portion of the first diffraction grating where light seeps out, a groove is covered with an insulating film, and the insulating film contains at least one or more elements of Si, Zr, Al, Ta, Nb, Ti, In, O, and N.

11. A light emitting device comprising:
the distributed feedback semiconductor laser element according to claim 1;
a nonlinear optical element structured to generate a second harmonic of emission light of the distributed feedback semiconductor laser element; and
a filter structured to transmit the second harmonic.

12. A method of manufacturing a distributed feedback semiconductor laser element, the method comprising the steps of:
forming a multi-layered structure including a GaN substrate, a first conductivity-type semiconductor layer, a light emitting layer, and a second conductivity-type semiconductor layer;
forming a ridge stripe structure in the multi-layered structure;
forming a first diffraction grating adjacent to the ridge stripe structure; and
forming an insulating film inside a groove of the first diffraction grating, wherein
a groove depth d of the first diffraction grating is included in a range of 54.9 nm≤d≤200 nm, and a duty ratio duty is included in a range of an inequality (1):
$$- \sqrt[n]{\frac{d - c}{a}} + b ≦ duty ≦ \sqrt[n]{\frac{d - c}{a}} + b \qquad ( 1 )$$
using constants a, b, c, and n defined for an order of diffracted light.

13. The manufacturing method according to claim 12, further comprising a step of forming a second diffraction grating in a region adjacent to the ridge stripe structure simultaneously with formation of the first diffraction grating.

14. The manufacturing method according to claim 12, wherein the insulating film is formed by an atomic layer deposition (ALD) method.
